(19) United States
(12) Patent Application Publication
(10) Pub. No.: US 2020/0387766 A1
(43) Pub. Date: Dec. 10, 2020

(54) FLEXIBLE DATALOGGER SYSTEMS

(71) Applicant: SEMICONDUCTOR COMPONENTS INDUSTRIES, LLC, Phoenix, AZ (US)

(72) Inventors: Douglas Cameron SEITZ, Scottsdale, AZ (US); Ernest Gil ESTILLER, Gilbert, AZ (US); Walker MITCHELL, Mesa, AZ (US); E. William COWELL, III, Portland, OR (US)

(73) Assignee: SEMICONDUCTOR COMPONENTS INDUSTRIES, LLC, Phoenix, AZ (US)

(21) Appl. No.: 16/787,472

(22) Filed: Feb. 11, 2020

Related U.S. Application Data
(60) Provisional application No. 62/858,395, filed on Jun. 7, 2019.

(51) Int. Cl. G06K 19/07; G06K 19/077; H05K 1/09

(52) U.S. Cl. CPC G06K 19/0717; G06K 19/0723; G06K 19/07775; H05K 1/092; G06K 19/07705

(57) ABSTRACT

A data logger system is disclosed. Specific implementations include a flexible data logger system. The data logger system may include a flexible substrate and a radio-frequency identification (RFID) communications module coupled to the flexible substrate. The RFID communications module may include an antenna coupled with a RFID chip. The data logger system may also include a microprocessor and a memory module coupled to the flexible substrate, the microprocessor and the memory module electrically coupled with the RFID communications module. The data logger system may also include a temperature sensor coupled to the flexible substrate, the temperature sensor electrically coupled with the microprocessor and memory module, and a power source coupled to the flexible substrate, the power source electrically coupled with the microprocessor, the memory module, the temperature sensor, and the RFID communications module.

### CROSS REFERENCE TO RELATED APPLICATIONS

This document claims the benefit of the filing date of U.S. Provisional Patent Application 62/858,395, entitled “Flexible Printed RFID Data Logger” to Seitz, et al. which was filed on Jun. 7, 2019, the disclosure of which is hereby incorporated entirely herein by reference.

### BACKGROUND

### 1. Technical Field

Aspects of this document relate generally to semiconductor devices. More specific implementations involve semiconductor devices used in data logger systems.

### 2. Background

Sensor systems gather information about a desired parameter. Examples of sensor systems include those designed to measure the temperature of an object or an ambient environment.

### SUMMARY

Implementations of a data logger system may include a flexible substrate and a radio-frequency identification (RFID) communications module coupled to the flexible substrate. The RFID communications module may include an antenna coupled with a RFID chip. The data logger system may also include a microprocessor and a memory module coupled to the flexible substrate, the microprocessor and the memory module electrically coupled with the RFID communications module. The data logger system may also include a temperature sensor coupled to the flexible substrate, the temperature sensor electrically coupled with the microprocessor and memory module, and a power source coupled to the flexible substrate, the power source electrically coupled with the microprocessor, the memory module, the temperature sensor, and the RFID communications module.

Implementations of a data logger system may include one, all, or any of the following:

The data logger system may include a light-emitting diode (LED) coupled to the flexible substrate and electrically coupled with the power source.

The flexible substrate may include a polymeric material.

The flexible substrate may be formed of polyethylene terephthalate (PET).

The data logger system may include a plurality of leads and a plurality of die attach components. The plurality of leads and the plurality of die attach components may be formed of electrically conductive ink screen printed onto the flexible substrate.

The data logger system may include a ground plane printed on a side of the flexible substrate.

Implementations of a data logger system may include a radio-frequency identification (RFID) communications module including an antenna and a RFID chip. The data logger system may also include a microprocessor and a memory module coupled with the RFID communications module. The data logger system may also include a sensor coupled with the microprocessor and memory module. The microprocessor, the memory module, the sensor, and the RFID communications module may be electrically coupled to a power source through a plurality of traces. The RFID communications module, the microprocessor, the memory module, the sensor, and the plurality of traces may all be coupled directly to a flexible substrate.

Implementations of a data logger system may include one, all, or any of the following:

The sensor may be a sensor selected from the group consisting of a temperature sensor, a moisture sensor, a humidity sensor, an accelerometer, a magnetic sensor, a gas sensor, a light sensor, or a xylene gas sensor, and in any combination thereof.

The data logger system may include a light-emitting diode (LED) coupled directly to the flexible substrate.

The flexible substrate may be formed of polyethylene terephthalate (PET).

The data logger system may include a plurality of leads and a plurality of die attach components. The plurality of leads and the plurality of die attach components may be formed of electrically conductive ink screen printed onto the flexible substrate.

The data logger system may include a ground plane printed on a side of the flexible substrate.

Implementations of a flexible data logger system may include a radio-frequency identification (RFID) communications module including an antenna and a RFID chip. The flexible data logger may also include a microprocessor and a memory module coupled with the RFID communications module, and a sensor coupled with the microprocessor and memory module. The microprocessor, the memory module, the sensor, and the RFID communications module may be electrically coupled to a power source through a plurality of traces. The RFID communications module, the microprocessor, the memory module, the sensor, and the plurality of traces may all be coupled directly to a flexible substrate. The flexible data logger system may be configured to be associated with a container to be tracked.

Implementations of a flexible data logger system may include one, all, or any of the following:

The sensor may be configured to provide temperature data associated with the container.

The memory module may be configured to store the temperature data.

The flexible data logger system may be configured to couple with the container inside the container, outside the container, or under a label coupled to the container.

The flexible data logger system may include a light-emitting diode (LED) configured to activate in response to a signal from the microprocessor.

The signal from the microprocessor may be sent in response to a change of a state of one or more bits in the memory module.

The sensor may be a temperature sensor configured to be programmable with one or more temperature thresholds.

The flexible substrate may be configured to store data related to mechanical and environmental handling of the container through a transportation process.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 illustrates a block diagram of an implementation of a data logger system;

FIG. 2 illustrates an implementation of a flexible substrate;

FIG. 3 illustrates a plurality of flexible substrates;

FIG. 4 illustrates an implementation of a flexible substrate with leads and traces; and

FIG. 5 illustrates a diagram of an implementation of a method of data logging using the data logger system.

### DESCRIPTION

This disclosure, its aspects and implementations, are not limited to the specific components, assembly procedures or method elements disclosed herein. Many additional components, assembly procedures and/or method elements known in the art consistent with the intended flexible data logger system will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such flexible data logger systems, and implementing components and methods, consistent with the intended operation and methods.

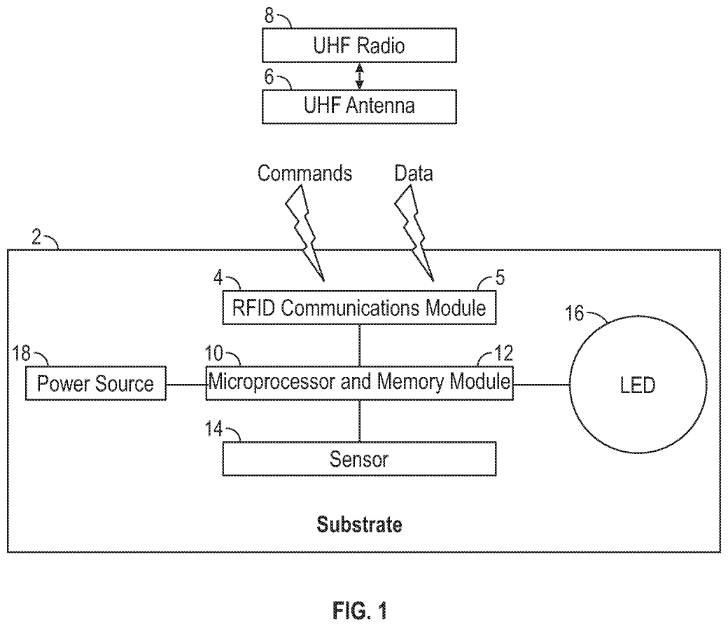

Referring to FIG. 1, a block diagram of an implementation of a data logger system is illustrated. The system utilizes a flexible substrate 2 to which the various components of the data logger system are coupled. As illustrated, the system includes a radio-frequency identification (RFID) communications module 4 that includes an RFID chip 5, an antenna 6, and a radio 8 coupled with the antenna 6, coupled therewith. A microprocessor 10 and memory module 12 are electrically coupled with the RFID communications module 4 and work with the RFID communications module 4 to transmit, receive, process, and store system data. A sensor 14 is electrically coupled with the microprocessor 10 and memory module 12. In various implementations, the sensor may be a temperature sensor. In other various implementations, a light-emitting diode (LED) 16 may be coupled to the flexible substrate 2 and a power source. A power source 18 is coupled with the flexible substrate 2 and is electrically coupled with the microprocessor 10 and memory module 12, the sensor 14, and the RFID communications module 4 via connections/traces provided on flexible substrate 2. As used herein, “flexible” indicates the ability of the substrate to reversibly deflect without damage beyond a radius of curvature of less than 100 mm. While various implementations that utilize flexible substrates are described herein, it will be apparent that various of the principles disclosed herein could be applied to substrates with a radius of curvature greater than 100 mm (“rigid substrates”).

Still referring to FIG. 1, the sensor 14 is coupled with the microprocessor 10 and the memory module 12 and provides analog and/or digital data regarding mechanical and/or environmental elements being experienced by the sensor 14. In various implementations, the sensor may be a temperature sensor. The sensor 14 may continuously supply the analog and/or digital data or may be woken up by the microprocessor 10 and the memory module 12 periodically to take measurements and supply the data. Examples of sensors that may be employed may include, by non-limiting example, thermocouples, thermistors, and any other device capable of outputting a temperature dependent electrical signal. In other implementations, any of a wide variety of other sensor types could be employed in various system implementations. By non-limiting example, moisture sensors, humidity sensors, accelerometers, magnetic sensors, gas sensors, light sensors, and any other sensor type designed to track/record a parameter relevant to a particular good in any particular container may be employed in various implementations. In particular implementations, a xylene gas sensor may be included which may be used to track the ripeness of particular fruits in the container/package to which the flexible data logger system is coupled.

Still referring to FIG. 1, a wide variety of microprocessor types and memory module types may be employed in various system implementations. Because of the use of a microprocessor and memory module, the flexible data logger systems disclosed herein may be active RFID systems rather than purely passive RFID systems which operate only via receiving power from a radio-frequency (RF) source used to scan/read passive RFID systems. Therefore, microprocessor and memory module types that draw as little power/current/voltage as possible when in a sleep condition may be used.

In various implementations, the data received from the sensor 14 may be stored permanently in on-board memory included in the microprocessor 10 itself. The on-board memory may be volatile or non-volatile depending on the microprocessor design. In various implementations, however, non-volatile memory may be used to ensure data storage if the battery power is removed/interrupted. Also, non-volatile memory may allow the system to consume less power as no voltage may need to be applied to the memory during operation to ensure the memory state is retained as when volatile memory is used. In those implementations where all data storage is handled by on-board memory, the number of components needed to form the system on the flexible substrate may be reduced.

In other implementations, a separate memory chip/components may be coupled with the microprocessor 10 via the flexible substrate 2 and/or a direct connection separate from the flexible substrate 2. A wide variety of memory types may be employed in various implementations, including, by non-limiting example, random access memory (RAM), non-volatile RAM, electrically erasable programmable read-only memory (EEPROM), flash memory (NAND or NOR), ferroelectric RAM (FeRAM), resistive RAM (ReRAM), magnetoelectric RAM (MeRAM), external ram (XRAM), and any other low power memory type.

Still referring to FIG. 1, the RFID communications module 4 includes the RFID chip 8 coupled with one or more antennas 6 that handles radio frequency sending and receiving (a transceiver) in the UHF range of the radio frequency spectrum (between about 300 MHz to about 1 GHz). In a particular implementation, the RFID communications module 4 employs two antennas, one a dipole and another a loop antenna, which are both coupled to a semiconductor die that includes a microprocessor and memory module in communication with the microprocessor. In such an implementations, the semiconductor die then communicates via routing on the flexible interconnect with the microprocessor 10 and memory module 12. In other various implementations, however, other RFID communication protocols and standards may be employed in combination with various RFID chip and antenna designs.

Still referring to FIG. 1, the power source 18 is coupled with all of the various components of the system through the flexible substrate 2, such as the microprocessor 10, the memory module 12, the sensor 14, and the RFID communications module 4. A wide variety of power source types may be employed in various implementations. In various implementations, the power source may be a battery. In various implementations, the power source may be sized to have a perimeter that fits within a perimeter of the flexible substrate 2. In various implementations, the size of the power source may range between about 36 mm-60 mm×46 mm-72 mm. In still other implementations, a wide variety of non-rechargeable power source chemistries may be employed is various implementations, including, by non-limiting example, lithium manganese dioxide, lithium sulfur dioxide, lithium thionyl chloride, and lithium oxygen, zinc-manganese dioxide-zinc chloride, zinc-carbon, zinc-chloride, and other alkaline power source types. Where the power source is intended to be rechargeable at least once, other rechargeable power source chemistries may be employed, including, by non-limiting example, lithium-ion polymer, zinc-manganese, and Zn-air, and other power source chemistries capable of being recharged. In still other implementations, the flexible substrate 2 may be sized to be coextensive with the perimeter of the power source or may, in some implementations, be smaller than the perimeter of the power source. In such implementations, the flexibility of the power source may enable the flexible substrate to bend to the extent the power source is flexible itself

In other implementations, the power source may not be flexible or substantially flexible. In such implementations, the power source may be single use or rechargeable and may employ any of the power source chemistries disclosed herein, along with others including, by non-limiting example, silver-silver oxide, zinc-oxygen, lithium-manganese dioxide, lithium-carbon monofluoride, lithium-copper oxide, nickel oxyhydroxide-manganese dioxide, and any other alkaline and/or rechargeable power source chemistry type.

In various system implementations disclosed herein, the power source 18 may be fixedly or removably coupled to the flexible substrate 2 material itself via an attachment process or via a pocket attached to the flexible substrate 2 material. In systems where the power source 18 is included in a pocket coupled to the flexible substrate 2 material, the power source/pocket may be the highest/thickest portion of the flexible data logger system. The power source may be held in the pocket with an adhesive. In such implementations, the power source may be coated at least partially with a material that does not react with the adhesive. The adhesive may be one that retains tackiness across a wide temperature range consistent with the operating temperature range of the power source itself

In various implementations where the flexible data logger system is held fully or partially to a container via a label, a pull off tab may be included in the structure of the label to allow a user to remove the tab and remove the power source through exposure under the material of the tab (or to access a pocket which holds the power source). In such implementations, the pull off tab may be shadowed from the adhesive, which coats the surface(s) of the label to allow the pull off tab to be more easily separated from the material of the label. Where pull off tabs are utilized in the label material, in various implementations, other portions of the flexible data logger system (chips, memory, etc.) may be removed when the pull off tab is separated (or may be removed by the user through the opening in the label material after the tab is separated). In some implementations, the power source 18 may not be included in a pocket and may be coupled directly to the flexible substrate 2 through an adhesive like any disclosed herein.

The various flexible data logger systems disclosed herein may be made reusable through the capability to remove the discharged power source as the discharged power source can be replaced with a charged power source. With the new charged power source, the flexible data logger system can then be reused to track sensor data using any of the systems and methods disclosed herein. Also, in various implementations, the ability to remove the power source via the pocket may also allow for disposal of the flexible data logger system after use to in accordance with any regulatory and/or environmental requirements.

In various use conditions like those disclosed herein, the power source may have a capacity between about 1 milliamp hour or higher. In particular implementations, the power source may have a capacity between about 1 milliamp hour to about 100 milliamp hours. In other implementations, the power source may have a capacity between about 5 milliamp hours to about 100 milliamp hours. In some other implementations, by non-limiting example, power sources such as vibration energy generation, thermal energy generation, light energy generation (solar), and any other power source that can be miniaturized to fit within the dimensions of the system, may be used. In some implementations, the power source may be rechargeable via a wireless power charging coil included in the flexible substrate which is coupled to the power source and which is set to resonate with a wireless charging system when placed adjacent the charging system.

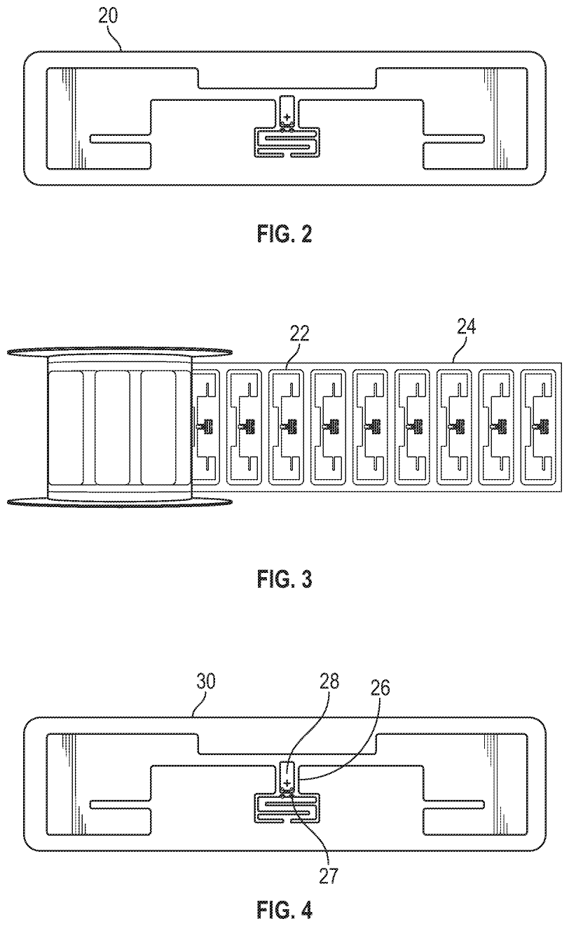

Referring to FIG. 2, an implementation of a flexible substrate is illustrated. Various flexible substrate types may be employed in various flexible data logger system implementations. As illustrated, various antenna designs have been formed on a flexible polymeric material. In other various implementations, the flexible substrate 20 is formed of polyethylene terephthalate (PET).

Referring to FIG. 3, a plurality of flexible substrates is illustrated. In various implementations, each flexible substrate 22 of a plurality of flexible substrates may be configured to be stored on a roll tape 24, as illustrated. In various implementations, the flexible substrate 22 may be configured to be reusable. In still other implementations, the flexible substrate 22 and/or the flexible data logger system may be configured to couple with a container inside the container, outside the container, or under a label coupled to the container.

Referring to FIG. 4, an implementation of a flexible substrate with leads and traces is illustrated. Various leads 27 and traces 26 have been formed on the flexible substrate 30 to which have been coupled a semiconductor die 28. A wide variety of components and inputs/outputs can be created using a flexible substrate in various implementations. For example, in the implementation illustrated in FIG. 4, the flexible substrate 30 forms a radio transceiver system that includes a sensor. As illustrated, the various inputs/outputs of the system are formed as leads 27 on the flexible substrate 30 while rigid chips like a microcontroller and semiconductor die 28 are bonded to the flexible substrate 30 using various techniques. In particular implementations, the flexible substrate 30 is formed of polyethylene terephthalate (PET) and the various leads 27 and die attach components are formed of electrically conductive ink that is screen printed onto the substrate material. In various system implementations, the flexible substrates may be printed on one side or both sides of the substrate material. In particular implementations, a ground plane is printed on a backside of the substrate material. In various implementations, no routing may be printed on the backside of the substrate material due to layer to layer registration issues (front to back). In some implementations, polyimides may also be used as the flexible substrate material. The use of PET may be desirable in some implementations because of its cheaper cost relative to various polyimide materials.

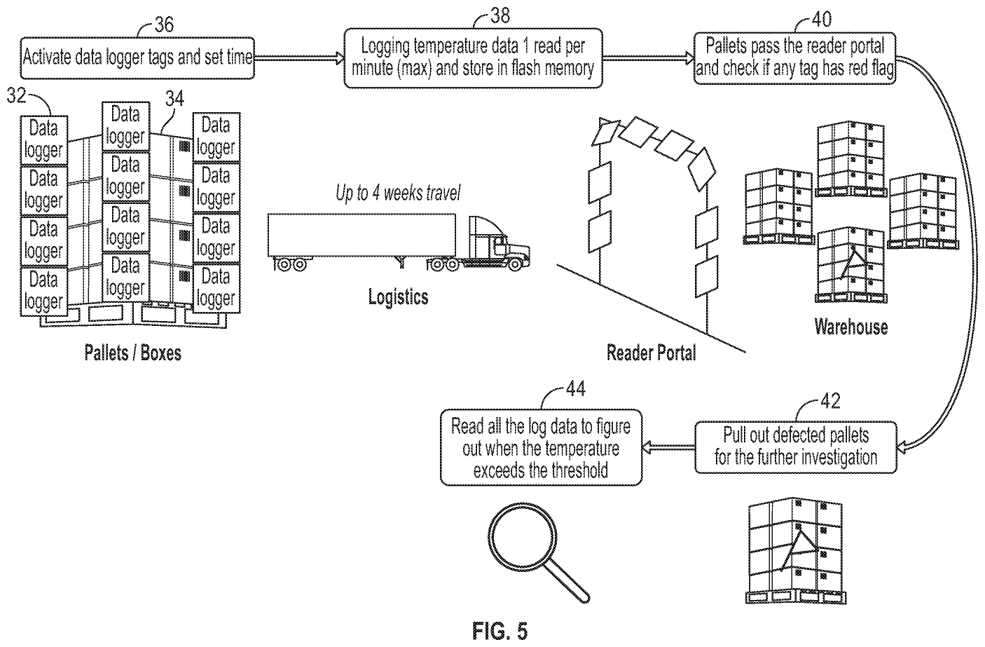

Referring to FIG. 5, a diagram of an implementation of a method of data logging using the data logger system is illustrated. In various implementations, the flexible data logger 32 is configured to be associated with a container 34 to be tracked. In such implementations, the flexible data logger includes the elements previously described. In various implementations, the flexible data logger 32 is associated with a box or other container 34 that holds a temperature-sensitive good (produce, electronics, meat, or any other object where temperature conditions are desired to be tracked). The association with the box/container 34 may take place in a variety ways. In one process implementation, the flexible data logger 32 may be placed inside the box/container 34 through dropping it into the box or container 34. In another process implementation, the flexible data logger 32 may be coupled to the outside of the box/container 34 through an adhesive. In process implementations where the flexible data logger 32 is coupled to the outside of the box/container 34, the flexible data logger 32 may be coupled to/under a printed label which acts to provide optical identification for the box/container 34.

In various implementations where a label is coupled to the flexible data logger is utilized to provide optical identification, the label may be previously applied to the flexible data logger or may be applied using a printer at the time the flexible data logger is coupled to the outside of the box/container.

Still referring to FIG. 5, and as described previously, the flexible data logger 32 includes a sensor, which may be a temperature sensor, in various implementations. In such implementations, the sensor may be configured to provide temperature data associated with the container 34. A memory module included in the flexible data logger may be configured to store the temperature data. Furthermore, the temperature sensor may be configured to be programmable with one or more temperature thresholds. In such implementations, the temperature sensor may be configured to measure, read, or detect, the temperature or temperature changes of the container 34 or the contents of the container 34. In such implementations, if a change is detected, or a threshold is reached, a signal from a microprocessor of the flexible data logger 32 is sent in response to the change of a state of one or more bits in the memory module of the flexible data logger 32. In other various implementations, a light-emitting diode (LED) 16 may be included with the flexible data logger 32 and may be configured to activate in response to the signal from the microprocessor, and may act as a visual indicator of the change of a state of the one or more bits of the memory module associated with a change to the container 34.

Still referring to FIG. 5, the flexible data logger 32 or flexible substrate stores data related to mechanical and environmental handling of the container 34 through a transportation process, which is illustrated in FIG. 5. First, the flexible data loggers 32 are activated 36 and a time may be set. Next, the sensor data is logged 38 as the container 34 is transported or stored. Next, each container 34 is passed 40 under a reader portal. The reader portal may be configured to look for an indicator or a signal that the state of the one or more bits of the memory module has changed. Finally, the tainted/flagged containers may be pulled 42 and separated from the rest, and a data log may be generated 44 from the sensor data and data stored in the memory module.

In places where the description above refers to particular implementations of a flexible data logger system and implementing components, sub-components, methods and sub-methods, it should be readily apparent that a number of modifications may be made without departing from the spirit thereof and that these implementations, implementing components, sub-components, methods and sub-methods may be applied to other flexible data logger systems.

What is claimed is:

1. A data logger system, comprising:
a flexible substrate;
a radio-frequency identification (RFID) communications module coupled to the flexible substrate, the RFID communications module comprising an antenna coupled with a RFID chip;
a microprocessor and a memory module coupled to the flexible substrate, the microprocessor and the memory module electrically coupled with the RFID communications module;
a temperature sensor coupled to the flexible substrate, the temperature sensor electrically coupled with the microprocessor and memory module; and
a power source coupled to the flexible substrate, the power source electrically coupled with the microprocessor, the memory module, the temperature sensor, and the RFID communications module.

2. The system of claim 1, further comprising a light-emitting diode (LED) coupled to the flexible substrate and electrically coupled with the power source.

3. The system of claim 1, wherein the flexible substrate comprises a polymeric material.

4. The system of claim 1, wherein the flexible substrate is formed of polyethylene terephthalate (PET).

5. The system of claim 1, further comprising a plurality of leads and a plurality of die attach components, wherein the plurality of leads and the plurality of die attach components are formed of electrically conductive ink screen printed onto the flexible substrate.

6. The system of claim 1, further comprising a ground plane printed on a side of the flexible substrate.

7. A data logger system, comprising:
a radio-frequency identification (RFID) communications module comprising an antenna and a RFID chip;
a microprocessor and a memory module coupled with the RFID communications module; and
a sensor coupled with the microprocessor and memory module;
wherein the microprocessor, the memory module, the sensor, and the RFID communications module are electrically coupled to a power source through a plurality of traces; and
wherein the RFID communications module, the microprocessor, the memory module, the sensor, and the plurality of traces are all coupled directly to a flexible substrate.

8. The system of claim 7, wherein the sensor is a sensor selected from the group consisting of a temperature sensor, a moisture sensor, a humidity sensor, an accelerometer, a magnetic sensor, a gas sensor, a light sensor, or a xylene gas sensor, and any combination thereof.

9. The system of claim 7, further comprising a light-emitting diode (LED) coupled directly to the flexible substrate.

10. The system of claim 7, wherein the flexible substrate is formed of polyethylene terephthalate (PET).

11. The system of claim 7, further comprising a plurality of leads and a plurality of die attach components, wherein the plurality of leads and the plurality of die attach components are formed of electrically conductive ink screen printed onto the flexible substrate.

12. The system of claim 7, further comprising a ground plane printed on a side of the flexible substrate.

13. A flexible data logger system, comprising:
a radio-frequency identification (RFID) communications module comprising an antenna and a RFID chip;
a microprocessor and a memory module coupled with the RFID communications module; and
a sensor coupled with the microprocessor and memory module;
wherein the microprocessor, the memory module, the sensor, and the RFID communications module are electrically coupled to a power source through a plurality of traces;
wherein the RFID communications module, the microprocessor, the memory module, the sensor, and the plurality of traces are all coupled directly to a flexible substrate; and
wherein the flexible data logger system is configured to be associated with a container to be tracked.

14. The system of claim 13, wherein the sensor is configured to provide temperature data associated with the container.

15. The system of claim 14, wherein the memory module is configured to store the temperature data.

16. The system of claim 13, wherein the flexible data logger system is configured to couple with the container inside the container, outside the container, or under a label coupled to the container.

17. The system of claim 13, further comprising a light-emitting diode (LED) configured to activate in response to a signal from the microprocessor.

18. The system of claim 17, wherein the signal from the microprocessor is sent in response to a change of a state of one or more bits in the memory module.

19. The system of claim 13, wherein the sensor is a temperature sensor configured to be programmable with one or more temperature thresholds.

20. The system of claim 13, wherein the flexible substrate is configured to store data related to mechanical and environmental handling of the container through a transportation process.
